(19) United States
(12) Patent Application Publication
(10) Pub. No.: US 2026/0266886 A1
(43) Pub. Date: Sep. 10, 2026

(54) APPARATUS, METHOD, AND SYSTEM FOR DETECTING FALLEN POWER LINE OR FOR DETECTING SAG IN POWER LINE

(71) Applicant: SAUDI ARABIAN OIL COMPANY, Dhahran (SA)

(72) Inventor: Jose Sarkis, Dhahran (SA)

(73) Assignee: SAUDI ARABIAN OIL COMPANY, Dhahran (SA)

(21) Appl. No.: 19/073,097

(22) Filed: Mar. 7, 2025

(51) Int. Cl. G01R 31/08; G01B 11/06; G01R 1/04; G08B 21/18

(52) U.S. Cl. CPC G01R 31/085; G01B 11/0608; G01R 1/04; G08B 21/182; G08B 21/185

(57) ABSTRACT

An apparatus for detecting a fallen power line or for detecting a sag in the power line includes: a housing that is configured to be disposed on the power line; one or more proximity sensors that are disposed on or inside the housing, wherein the one or more proximity sensors measure a height from the apparatus to a ground level below the power line; a transmitter, wherein in response to the one or more proximity sensors measuring the height as being lower than a predetermined height threshold, the transmitter is configured to transmit a signal to a transceiver that is disposed separately from the apparatus; and a battery that powers the transmitter and the one or more proximity sensors.

### BACKGROUND

In high-voltage facilities, such as 13.8 kV transmission lines, a fallen power line on the ground or the power line hanging too close to the ground may pose a safety risk. Although some facilities have ground fault protection relays that can shut down the power line, in terrains that have high electrical resistivity the protection replays may not detect and clear up the ground fault due to the high electrical resistivity. Such terrains may be rocky or dry deserts areas where the electrical resistivity of the power system in the terrain might be as high as 5,000 to 1,000,000 Ω/m. Thus, in such terrains, a protection relay may not detect an energized power line that has fallen on the ground, which threatens safety of personnel, living species, and stability of the corresponding electrical system. These are recurring issues that operation and maintenance personnel encounter in high-voltage facilities.

### SUMMARY

This summary is provided to introduce a selection of concepts that are further described below in the detailed description. This summary is not intended to identify key or essential features of the claimed subject matter, nor is it intended to be used as an aid in limiting the scope of the claimed subject matter.

One or more embodiments disclosed herein relate to an apparatus for detecting a fallen power line or for detecting a sag in the power line. The apparatus comprises: a housing that is configured to be disposed on the power line; one or more proximity sensors that are disposed on or inside the housing, wherein the one or more proximity sensors measure a height from the apparatus to a ground level below the power line; a transmitter, wherein in response to the one or more proximity sensors measuring the height as being lower than a predetermined height threshold, the transmitter is configured to transmit a signal to a transceiver that is disposed separately from the apparatus; and a battery that powers the transmitter and the one or more proximity sensors.

One or more embodiments disclosed herein relate to a method for detecting a fallen power line or for detecting a sag in the power line by an apparatus that is disposed on the power line. The method comprises: measuring, by one or more proximity sensors disposed on or inside a housing of the apparatus, a height of the apparatus from a ground level below the power line; in response to the one or more proximity sensors measuring the height as being lower than a predetermined height threshold, transmitting, by a transmitter of the apparatus, a signal to a transceiver that is disposed separately from the apparatus, wherein the transmitter and the one or more proximity sensors are powered by a battery of the apparatus; receiving the signal, by the transceiver, from the transmitter of the apparatus; transmitting the signal, by the transceiver, to a receiver of an electric substation; analyzing the received signal, by the electric substation, to determine whether the power line has fallen or to determine whether the sag in the power line is more than a sag threshold; and in response to determining that the power line has fallen or determining that the sag in the power line is more than the sag threshold, configuring a circuit breaker to shut down the power line or configuring the electric substation to raise an alarm.

One or more embodiments disclosed herein relate to a system for detecting a fallen power line or for detecting a sag in the power line. The system comprises: an apparatus that detects a height of the apparatus from a ground level below the power line; a transceiver, and an electric substation. The apparatus comprises: a housing that is configured to be disposed on the power line; one or more proximity sensors that are disposed on or inside the housing, wherein the one or more proximity sensors measure the height of the apparatus from the ground level below the power line; a transmitter, wherein in response to the one or more proximity sensors measuring the height as being lower than a predetermined height threshold, the transmitter is configured to transmit a signal to a transceiver that is disposed separately from the apparatus; and a battery that powers the transmitter and the one or more proximity sensors. The transceiver transmits the signal to a receiver of the electric substation. The substation is configured to analyze the received signal to determine whether the power line has fallen or to determine whether the sag in the power line is more than a sag threshold. The electric substation comprises a circuit breaker or an alarm system. In response to the electric substation determining that the power line has fallen or in response to the electric substation determining that the sag in the power line is more than the sag threshold, the electric substation configures the circuit breaker to shut down the power line or configures the alarm system to raise an alarm.

Other aspects and advantages of the claimed subject matter will be apparent from the following description and the appended claims.

### BRIEF DESCRIPTION OF DRAWINGS

Specific embodiments of the disclosed technology will now be described in detail with reference to the accompanying figures. Like elements in the various figures are denoted by like reference numerals for consistency. The sizes and relative positions of elements in the drawings are not necessarily drawn to scale. For example, the shapes of various elements and angles are not necessarily drawn to scale, and some of these elements may be arbitrarily enlarged and positioned to improve drawing legibility. Further, the particular shapes of the elements as drawn are not necessarily intended to convey any information regarding the actual shape of the particular elements and have been solely selected for ease of recognition in the drawing.

FIG. 1 illustrates a high voltage power system for detecting the height of a detecting apparatus from a ground level, in accordance with one or more embodiments.

FIG. 2 illustrates a detecting apparatus for detecting the height of the detecting apparatus from a ground level, in accordance with one or more embodiments.

FIG. 3 illustrates a system for detecting a fallen power line or for detecting a sag in a power line, in accordance with one or more embodiments.

FIG. 4 illustrates a detecting apparatus for detecting a fallen power line or for detecting a sag in a power line, in accordance with one or more embodiments.

FIG. 5 illustrates a flowchart for an operation of a system for detecting a fallen power line or for detecting a sag in a power line, in accordance with one or more embodiments.

### DETAILED DESCRIPTION

In the following detailed description of embodiments of the disclosure, numerous specific details are set forth in order to provide a more thorough understanding of the disclosure. However, it will be apparent to one of ordinary skill in the art that the disclosure may be practiced without these specific details. In other instances, well-known features have not been described in detail to avoid unnecessarily complicating the description.

Throughout the application, ordinal numbers (e.g., first, second, third, etc.) may be used as an adjective for an element (i.e., any noun in the application). The use of ordinal numbers is not to imply or create any particular ordering of the elements nor to limit any element to being only a single element unless expressly disclosed, such as using the terms “before,” “after,” “single,” and other such terminology. Rather, the use of ordinal numbers is to distinguish between the elements. By way of an example, a first element is distinct from a second element, and the first element may encompass more than one element and succeed (or precede) the second element in an ordering of elements.

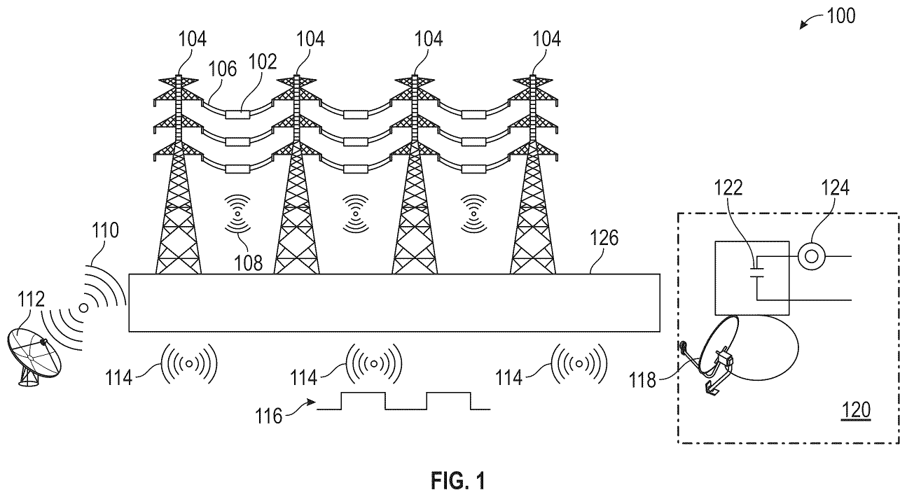

In the following description of FIGS. 1-5, any component described regarding a figure, in various embodiments disclosed herein, may be equivalent to one or more like-named components described with regard to any other figure. For brevity, descriptions of these components will not be repeated regarding each figure. Thus, each and every embodiment of the components of each figure is incorporated by reference and assumed to be optionally present within every other figure having one or more like-named components. Additionally, in accordance with various embodiments disclosed herein, any description of the components of a figure is to be interpreted as an optional embodiment which may be implemented in addition to, in conjunction with, or in place of the embodiments described with regard to a corresponding like-named component in any other figure.

It is to be understood that the singular forms “a,” “an,” and “the” include plural referents unless the context clearly dictates otherwise. Thus, for example, reference to “a transmission line” includes reference to one or more of such transmission lines.

Terms such as “approximately,” “substantially,” etc., mean that the recited characteristic, parameter, or value need not be achieved exactly, but that deviations or variations, including for example, tolerances, measurement error, measurement accuracy limitations and other factors known to those of skill in the art, may occur in amounts that do not preclude the effect the characteristic was intended to provide.

It is to be understood that one or more of the steps shown in the flowcharts may be omitted, repeated, and/or performed in a different order than the order shown. Accordingly, the scope disclosed herein should not be considered limited to the specific arrangement of steps shown in the flowcharts.

Embodiments disclosed herein relate to detecting apparatus, methods, and systems, for detecting a fallen power line or for detecting a sag in a power line, to reduce risks of electrocution of personnel or living species in vicinity of the power line and maintain the stability of the corresponding electrical system. Hereinafter, the “detecting apparatus” will be referred to as simply “apparatus.” The apparatus may be disposed on a power line. For example, the apparatus may be fixed to the power line via stoppers (e.g., bracket stoppers) that prevent the apparatus sliding on the power line or slipping off the power line after the power line has fallen. The apparatus may be disposed at a central location of each span, such as the middle, of the power line where the power line has the largest sag. In other words, the apparatus may be mounted in the middle of the power line where the power line is at its lowest elevation.

In the embodiments disclosed herein, the apparatus detects the height (“H”) of the apparatus from the ground level that is below the apparatus. The height of the apparatus from the ground level represents the height of the power line from the ground level, and thus, reflects the sag of the power line or identifies whether the power line has fallen/broken. Upon the apparatus detecting that the height of the apparatus from the ground level is below a predetermined height threshold, the apparatus transmits a signal to a transceiver that is separate from the apparatus and is within the transmission range of the apparatus. The signal indicates the height of the apparatus from the ground level and may indicate the power line or power line span that corresponds to the apparatus. In one or more embodiments, the transceiver may be located at ground level or may be mounted on an electric pole or pilon.

In one or more embodiments, the transceiver receives the signal from the apparatus and relays/transmits the signal to a receiver of an electric substation that is separate from the transceiver. To this end, the transceiver may boost the signal, modulate the signal, or perform any other alteration to the signal to make it more appropriate for transmission to the receiver of the electric substation. Hereinafter, the receiver of the electric substation will be referred to as “receiver,” for simplicity. The receiver may be an attached component of the electric substation or may be detached from the electric substation.

In one or more embodiments, after receiving the signal from the transceiver, the electric substation may alter the signal to a proper format to be readable by the electric substation. The electric substation may be equipped with metal clad switchgear(s) and incomer and feeder breaker(s). The electric substation may be under protection, metering, communication, or control scheme(s) to provide a reliable power supply to the system. For example, the electric substation may comprise a signal converter or other components to demodulate the signal or to make any other alterations on the signal.

FIG. 1 shows a system (100) for detecting a fallen power line (106) or for detecting excessive sag in a power line (106), in accordance with one or more embodiments. The system (100) includes an apparatus (102) (i.e., detecting apparatus) that is disposed on the power line(s) (106). The apparatus (102) may be disposed on a single power line or on a plurality of power lines depending on a specific design or safety procedure of the system (100). As shown in FIG. 1, an apparatus (102) may be disposed on each span of each power line (106). In some embodiments, a plurality of apparatuses (102) may be deployed on a single span of a power line.

In this disclosure, “power line” refers to the power line span that is disposed between two adjacent power poles, as shown in FIG. 1. For example, in FIG. 1, the power line span that is disposed between two adjacent electric poles (104) is referred to as the power line (106).

In one or more embodiments, the apparatus (102) may be sleeved into the power line (106) such that a sleeve covers both the apparatus (102) and the power line (106). For example, the apparatus (102) may be sleeved in an existing power line by having side clamps that secure the apparatus (102) in the power line so that the apparatus (102) is protected.

In one or more embodiments, the apparatus (102) may be fastened to the power line (106) via one or more fastener. Examples of the fastener may be glue, epoxy, bracket stoppers, clamps, etc.

In FIG. 1, the apparatus (102) is disposed in a central location, such as the middle, of the power line (106) where the power line is in its lowest height between the two corresponding electric poles (104) (i.e., where the power line (106) has the largest sag). This way, the apparatus (102) can detect the height of the power line (106) at its lowest elevation. Accordingly, the apparatus can also detect the sag of the power line (106). Sag is the vertical distance between the highest point of the power line (which typically is an attachment on a pole or tower) and the lowest point of the power line. Sag occurs due to the natural weight of the power line and external factors such as temperature, wind, and ice/snow loading. Proper sag calculations may be crucial to maintaining clearance from the ground and ensuring safety.

The apparatus (102) may measure the height of the power line (106) by emitting or transmitting a wave (108). In one or more embodiments, the wave (108) comprises infrared radiation for detecting the distance of the apparatus (102) from the ground level (126) below. For example, the apparatus (102) may comprise a Light Detection and Ranging (LiDAR) detector that detects the distance of the apparatus (102) from the ground level (126). In one or more embodiments, the apparatus (102) may comprise another type of infrared emitter/detector. For example, in some embodiments, the wave (108) may comprise a radio wave. For example, in some embodiments, the apparatus (102) may comprise a Radio Detection and Ranging (Radar) detector that detects the distance of the apparatus (102) from the ground level (126) using an emitted and reflected radio wave. In one or more embodiments, the wave (108) may comprise an acoustic wave. For example, the apparatus (102) may comprise a Sound Navigation and Ranging (Sonar) detector that detects the distance of the apparatus (102) from the ground level (126) using an emitted and reflected sonar wave.

In response to the apparatus (102) detecting the height as being below a predetermined height threshold, a transmitter of the apparatus (102) transmits a signal (110) to a transceiver (112) that is within the transmission range of the transmitter of the apparatus (102). In one or more embodiments, the signal (110) may comprise a tripping command for tripping a circuit breaker (124) that is associated with the power line (106), to shut down the power line (106). Or the signal (110) may comprise instructions based on which the electric substation (120) sends the tripping command to the circuit breaker (124) to shut down the power line (106). In one or more embodiments the signal (110) may comprise a command or an instruction based on which the electric substation (120) generates an alarm to alert personnel about safety issues. According to one or more embodiments, the transceiver (112) may communicate with a plurality of apparatuses (102).

According to one or more embodiments, the apparatus (102) transmits the signal (110) to the transceiver (112) only in response to determining that the height of the power line (106) from the ground level (126) meets a predetermined condition, such as being separated from the ground by less than a predetermined height threshold.

In one or more embodiments, the apparatus (102) measures the height for a predetermined time period before sending the signal (110) to avoid any false positives. Hereinafter, the predetermined time period is referred to as “predetermined time interval.” The false positives may be caused by, for example, detection errors in the apparatus (102) or transitory detections caused by passing vehicles, humans, animals, or objects in the area. For example, in one or more embodiments, the apparatus (102) may continuously measure the height during the predetermined time interval to ascertain that detecting the height below the predetermined height threshold is not influenced by false positives, but rather is caused because of a fallen power line (106) or an unsafe sag in the power line (106). For example, the apparatus (102) may determine whether the apparatus (102) has measured the height above the ground as being lower than the predetermined height threshold continuously during the predetermined time interval. If the height is lower than the predetermined height threshold at all times during the predetermined time interval, the apparatus (102) may transmit the signal (110) to the transceiver (112). Conversely, if the height not lower than the predetermined height threshold at all times during the predetermined time interval, the apparatus (102) may not transmit the signal (110) to the transceiver (112). In one or more embodiments, the predetermined time interval may be 5 seconds.

In another example, according to one or more embodiments, the apparatus (102) may measure the height at discrete times during the predetermined time interval to exclude false positives. For example, the apparatus (102) may measure the height at a first time and then measure the height at a second time that is after the first time by the predetermined time interval. If the measurements at the first time and second differ substantially, for example more than a predetermined difference threshold, then the apparatus (102) sends the signal (110) to the transceiver (112). The discrete measurement may reduce power consumption of the apparatus.

In one or more embodiments, the apparatus (102) may measure the height at a string of discrete times during the predetermined time interval and calculate a median value for the measured values (i.e., a median for the height measurement values). The apparatus (102) may exclude measured values that are too “spiky.” In one or more embodiments, being too spiky is defined as the case where the ratio between the measured value and the median value is more than a predetermined ratio threshold.

In one or more embodiments, the apparatus (102) may transmit a “faulty” equipment signal if the variance or standard deviation of the measurements exceed a predetermined value, or a value determined by analysis of previous time intervals.

In one or more embodiments, the predetermined time interval is determined based on an average crossing time of inhabitants or objects that cross a space below the power line (106), terrain conditions, weather conditions, or other factors that may affect the transitory height changes or erroneous measurements. For example, in an area where it is more possible for inhabitants (e.g., wildlife, human, personnel) or objects (e.g., vehicles) to cross the space below the power line (106) in in vicinity of the power line (106), the predetermined time interval may be determined to be long enough so that the presence of the inhabitants or objects shows sufficient inconsistency in the measurement results and thereby, the apparatus (102) can determine that the measured low height is a false positive. For example, the predetermined time interval may be determined based on the average time of the inhabitants or objects crossing the space below the power line (106), according to statistical data for the region where the power line (106) is disposed.

In one or more embodiments, the apparatus (102) may perform the height measurement repeatedly at a plurality of times. For example, the apparatus (102) may perform two, three, four, or more discrete height measurements and determine the false positives based on comparing the results of the measurements at the plurality of times. In one or more embodiments, the measuring times may be periodic with a predetermined period that may be equal to the predetermined time interval, for a predetermined number of measurements. In one or more embodiments, upon the results of the measurement at the plurality of times being substantially similar, the apparatus (102) will transmit the signal (110) to the transceiver (112). To this end, as described above, the apparatus (102) may determine whether or not to send the signal (110) based on determining whether the difference between the measurement results at the plurality of times would exceed a difference threshold.

In one or more embodiments, the apparatus (102) may be equipped with at least four proximity sensors, under a “voting” scheme where a specific number of detection signals detecting the height being less than the predetermined height threshold (N−1) may be considered as logic number “1,” which indicates “True.”

In one or more embodiments, the predetermined height threshold may be determined based on factors such as the terrain under the power line (106), temperature at the location of the power line (106), precipitation conditions, wind conditions, or other factors that may affect the sag of the power line. For example, because of snow accumulation on the power line (106), the sag in the power line (106) may increase and the system may determine the predetermined height threshold to account for the snow accumulation. In another example, because of changes in the temperature, the sag in the power line (106) may change as a result of expansion or contraction. Accordingly, these conditions may be considered in determining the predetermined height threshold.

According to one or more embodiments, the apparatus (102) transmits the signal (110) to the transceiver (112) only in response to determining that the detection of the height as being lower than the predetermined height threshold is a valid determination, i.e., not a false positive, as described above.

According to one or more embodiments, the transceiver (112) receives the signal (110) from the apparatus (102) and transmits the signal (114) to the receiver (118) of the electric substation (120). Before transmitting the signal (114) to the receiver (118), the transceiver (112) may modify the received signal (110) for transmission. For example, the transceiver (112) may comprise an amplifier that boosts the received signal (110) before transmission to the receiver (118). The transceiver (112) may also comprise a processor that may modulate the signal for a proper transmission based on several factors such as terrain, the distance between the transceiver (112) and the receiver (118), signaling protocols in the region (e.g., LTE, 5G, etc.), weather conditions, etc. For example, the transceiver (112) may modulate the received signal (110) into a pulse-type signal (116) or may amplify the received signal (110). Accordingly, the transceiver (112) properly relays the received signal (110) from the apparatus (102) to the receiver (118) of the electric substation (120).

In one or more embodiments, the transmitted signal (110) by the apparatus (102) to the transceiver (112) or the transmitted signal (114) by the transceiver to the receiver (118) may be radio frequency signals, i.e., in the radio frequency bandwidth or the electromagnetic spectrum, or may comprise radio frequency signals.

In one or more embodiments, a plurality of apparatuses (102) may transmit signals (110) to a common transceiver (112). Having a common transceiver (112) for a plurality of apparatuses (102) may provide simplicity and result in lower manufacturing, deployment, operation, and maintenance costs for the apparatuses (102) or other components of the system (100). For example, the apparatuses (102) may not need to be designed to have a long transmission range because they will transmit the signals (110) to a nearby transceiver (112) that will boost the received signals (110) and relay the boosted signals (114) to the receiver (118). This way, the apparatuses (102) could be designed to be less power consuming. A less power consuming apparatus (102) is beneficial because accessing the apparatus (102) for maintenance, for example for changing its battery, may be difficult. Accordingly, because the apparatuses (102) can transmit the signal (110) to a nearby common transceiver (112), each apparatus (110) may comprise a long-life battery, for example 10 years or more, that will supply the necessary power for the apparatus to operation (e.g., the height detection, the transmission of the signal (110) to the transceiver (112), etc.).

The electric substation (120) receives the signal (114), via the receiver (118), from the transceiver (112) and analyzes the signal (114). In one or more embodiments, the electric substation (120) may comprise a signal converter (122) and additional component(s) (e.g., memory, filter(s), rectifier(s), amplifier(s), processor(s), etc.) to process the received signal (114) and generate a command based on the received signal (114). For example, in one or more embodiments, the electric substation (120) may generate a tripping command and send it to the circuit breaker (124) to shut down the power line (106). For example, in one or more embodiments, the electric substation (120) may analyze the tripping command instructions included in the received signal (114), generate a dry type contact (NO) command based on the tripping command instructions, and sends the NO command to circuit breaker (124) that is associated with the corresponding power line (106). Or, in one or more embodiments, the electric substation (120) may generate an alarm command and send it to an alarm system to alarm maintenance personnel or other personnel regarding a safety issue regarding the power line (106). A NO command refers to a normally open (NO) dry contact that is used to control a circuit breaker. In electrical control systems, dry contacts (also called voltage-free or potential-free contacts) may be relay or switch contacts that do not supply any voltage themselves but instead act as a simple on/off switch.

For generating the NO command or raising the alarm, the electric substation (120) may analyze the signal with respect to other factors to determine whether it is necessary to generate the NO command or raise alarm, and may send the NO command only if the electric substation (120) finds it necessary. The other factors may comprise weather conditions, traffic conditions in the area of the power line (106), identification of the power line (106) that is included in the signal (114), etc.

Alternatively, in some embodiments, the electric substation (120) may entirely rely on the reception of the signal (114) from the transceiver (112) to determine whether to send the NO command or raise the alarm. In other words, for the electric substation (120), just receiving the signal (114) from the transceiver (112) may be sufficient to send the NO command or to raise the alarm.

According to one or more embodiments, only the proximity sensor(s) of the apparatus (102), detect the height and thereby detect the fallen power line or the sage in the power line (106). The height detection is not based on electrical field transient changes in the power line (106). In one or more embodiments, the height is detected only by the proximity sensors.

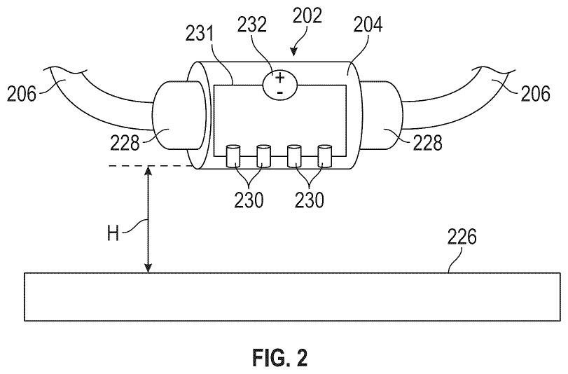

FIG. 2 shows the apparatus (202) disposed on the power line (206), in accordance with one or more embodiments. The apparatus (202) shown in FIG. 2 comprises a housing (204) that contains four of proximity sensors (230) that detect the height (H) of the apparatus from the ground level (226) below the apparatus (202). While FIG. 2 shows that the apparatus includes four proximity sensors (230), the apparatus may comprise other numbers of proximity sensors. For example, the apparatus may include only one, two, or any other number of proximity sensors based on a specific design and operation of the apparatus. In one or more embodiments, the number of the proximity sensors may depend on detection conditions, measurement requirements, terrain conditions, detection location, required precision, or other factors that affect determination of the height or affect reliability of the height detection.

In one or more embodiments, the housing (204) magnetically shields circuitries inside the apparatus (202) such as a pulse generator of the apparatus and/or the one or more proximity sensors (230). To this end, in one or more embodiments, the housing (204) may be made of an epoxy, a porcelain material, or a rubbery material, or a faraday cage. For example, the housing (204) may include aluminum/metal sheath/faraday cage wrapped up by an epoxy/rubbery composite to magnetically shield the circuitries inside the apparatus (202). For example, the proximity sensors (230), a radio frequency pulse generator, a micro antenna, and the battery (232) of the apparatus (202) may be housed in a magnetically shielded encasement that is sleeved/hollowed out in the power line (206). The battery (232) powers the proximity sensors (230) via the illustrative wiring connections (231). In another example, the proximity sensors (230), a radio frequency pulse generator, a micro antenna, and the battery (232) of the apparatus (202) may be shielded with aluminum/metal sheath/faraday cage wrapped up by an epoxy/rubbery composite.

According to one or more embodiments, the apparatus (202) is self-powered by incorporating a battery (232) that supplies the power necessary for the apparatus (202) to operate. For example, the battery (232) powers the proximity sensors (230) and other components of the apparatus (202). In one or more embodiments, such components may comprise a pulse generator, a processor, a memory, or a transmitter. According to one or more embodiments, the battery (232) may have a long lifetime, e.g., ten years or more. According to one or more embodiments, because the apparatus (202) transmits the signal to a nearby transceiver (which relays the signal to a farther electric substation) rather than directly transmitting the signal to the electric substation, the apparatus (202) could be designed to have lower power consumption. Thus, the battery's lifetime may last longer than would be the case where the apparatus (202) directly transmits the signal to the electric substation.

In FIG. 2, according to one or more embodiments, the apparatus (202) may be fixed to the power line (206) by brackets (228) (i.e., bracket stoppers). The brackets (228) that are disposed on the two opposite sides of the apparatus (202) prevent the apparatus (202) from slipping along the power line (206). For example, in the case where the power line (206) has fallen, the brackets (228) prevent the apparatus (202) from sliding and becoming detached from the power line on the ground.

In some embodiments, the proximity sensors (230) may use infrared radiation to detect H. For example, the proximity sensors (230) may comprise a LiDAR detector to measure H.

In one or more embodiments, the proximity sensors (230) may use radio-frequency radiation to detect H. For example, the proximity sensors (230) may comprise a Radar detector to measure H.

In one or more embodiments, the proximity sensors (230) may use acoustic waves to detect H. For example, the proximity sensors (230) may comprise a Sonar detector to measure H.

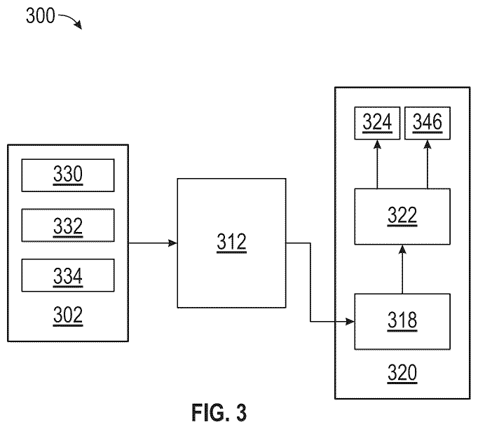

FIG. 3 shows a simplified diagram of the system (300), in accordance with one or more embodiments. The system (300) comprises an apparatus (302) (i.e., detecting apparatus) that comprises one or more proximity detectors (330), a battery (332), and a transmitter (334). In response to the proximity detectors (330) detecting that the height of the apparatus (302) is below a predetermined height threshold and that the apparatus (302) determines that the lower height is not caused by false positives, as described above, the transmitter (334) transmits a signal to a transceiver (312). To this end, the transmitter (334) may comprise a pulse generator to generate a pulse-type signal for transmission. The transceiver (312) relays the received signal to a receiver (318) of an electric substation (320). Then, a signal converter (322) of the electric substation (320) receives the signal from the receiver (318). The electric substation (320) processes the converted signal and determines whether the power line has fallen or that the sag in the power line is more than a predetermined sag threshold. The sag being more than a predetermined threshold may compromise safety of the personnel or living species around the power line or the integrity of the power system (300).

Using the signal converter (322), the electric substation (320) may generate a tripping command and send it to a circuit breaker (324) to shut down the power line. For example, in one or more embodiments, the electric substation (320) will generate a dry type contact (NO) command based on the tripping command instructions included in the received signal and sends the NO command to circuit breaker (324) that is associated to the power line. Or, in one or more embodiments, the electric substation (320) may generate an alarm command and send it to an alarm system (346), such as a Public Safety Announcement (PSA) system, to alarm maintenance personnel or other personnel regarding a safety issue. In one or more embodiments, the sag threshold is a threshold above which risks regarding safety of personnel, living species, or instability of the corresponding electrical system is not acceptable.

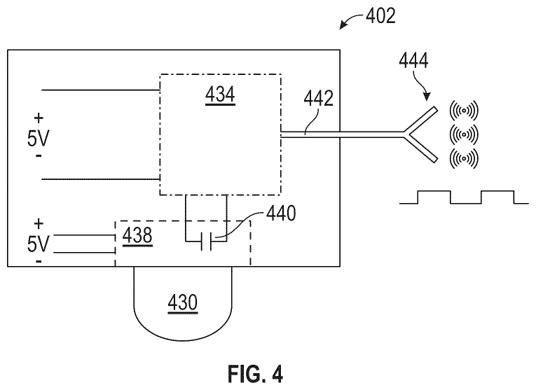

FIG. 4 shows a diagram of the apparatus (402), in accordance with one or more embodiments. The apparatus (402) includes one or more proximity sensors (430), a pulse generator (434), a circuitry for the proximity sensors (438) that is capable of generating information regarding a NO command (440), an analogue output (442), and an antenna (444) for transmitting the signal to the transceiver. The information regarding the NO command (440) may comprise, for example, information indicating that the height of the apparatus (402) is less than the predetermined height threshold or information indicating a tripping command for a circuit breaker. In one or more embodiments, the antenna (444) may be a micro antenna or an array of micro antennas. One or more of the antenna (444), the analogue output (442), and the pulse generator (434), may be considered components of a transmitter of the apparatus. A person of ordinary skill in the art acknowledges that a transmitter may include necessary components to modulate (e.g., modulating into a pulse-type signal), amplify, or perform other operations to prepare the signal for transmission.

In response to the proximity sensors (430) detecting the height of the apparatus (402) as being lower than a predetermined height threshold, the circuitry for the proximity sensors (438) send information regarding the NO command (440) to the pulse generator (434). To this end, the pulse generator (434) may receive a digital input from the circuitry for the proximity sensors (438). To this end, the circuitry for the proximity sensors (438) may measure the height during a predetermined time interval (e.g., 5 seconds), continuously or discretely, to determine that the measured height is not affected by false positives, as described above with respect to FIG. 1. If the circuitry for the proximity sensors (438) determines that the measurement is influenced by false positives, the circuitry for the proximity sensors (438) may not send the information regarding the NO command to the pulse generator (434).

In response to receiving the information regarding the NO command from the circuitry for the proximity sensors (438), the pulse generator (434) generates a pulsed-type signal, and the apparatus (402) sends the signal to the antenna (444) via the analogue output (442), to be transmitted to the transceiver by the antenna (444). To this end, the circuitry for the proximity sensors (438) may comprise a processor and a memory to perform the determination.

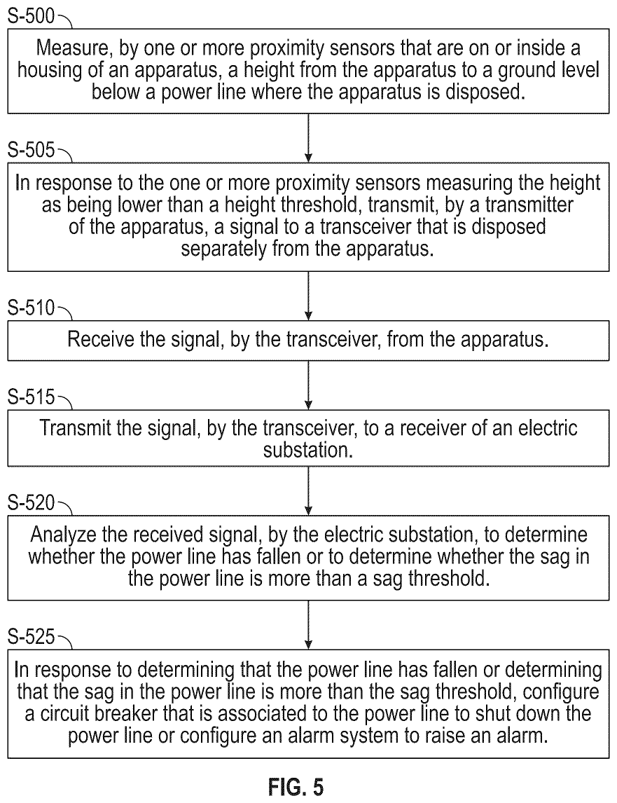

FIG. 5 illustrates a flowchart of a method for detecting a fallen power line or for detecting a sag in the power line. In one or more embodiments, one or more of the steps shown in FIG. 5 may be omitted, repeated, and/or performed in a different order than the order shown in FIG. 5. Accordingly, the scope of the invention should not be considered limited to the specific arrangement of steps shown in FIG. 5. Steps S-500 to S-525 shown in FIG. 5 are explained below.

In S-500, an apparatus measures, by one or more proximity sensors that are disposed on or inside a housing of the apparatus, a height of the apparatus from a ground level below a power line on which the apparatus is disposed. Measuring the height of the apparatus from the ground level may comprise measuring the height for a predetermined time interval to determine whether the measured height is affected by false positives. For example, as described above with reference to FIGS. 1-4, the apparatus (102, 202, 302, 402) measures the height (H) of the apparatus from the ground level (126, 226).

In S-505, in response to the one or more proximity sensors measuring the height as being lower than a predetermined height threshold, the apparatus transmits a signal to a transceiver that is disposed separately from the apparatus. For example, as described above with reference to FIGS. 1-4, in response to the apparatus (102, 202, 302, 402) determining that the height is lower than the predetermined height threshold, a transmitter of the apparatus (102, 202, 302, 402) transmits the signal (110) to the transceiver (112). The transmitter and the one or more proximity sensors are powered by a battery, as described above with reference to FIGS. 1-4.

In S-510, the transceiver receives the signal from the apparatus. And in S-515, the transceiver transmits the signal to a receiver of an electric substation. For example, as described above with reference to FIGS. 1-4, the transceiver (112, 312) receives the signal (110) from the apparatus (102, 202, 302, 402) and then transmits the signal (114) to the receiver (118, 318) of the electric substation (120, 320). To this end, as described above, the transceiver may boost the signal or perform any other modifications to the signal to make it more proper for transmission to the receiver (118, 318).

In S-520, the electric substation analyzes (e.g., parses) the received signal to determine whether the power line has fallen or to determine whether the sag in the power line is more than a sag threshold, for example as described above with reference to FIGS. 1 and 3.

In S-525, in response to the electric substation determining that the power line has fallen or determining that the sag in the power line is more than the sag threshold, the electric substation configures a circuit breaker that is associated to the power line to shut down the power line or configures an alarm system to raise an alarm. For example, as described above with reference to FIGS. 1 and 3, the electric substation (120, 320) configures the circuit breaker (124, 324) to shut down the power line or configures the alarm system (346) to raise an alarm regarding the hazardous condition of the power line.

The method may comprise additional steps, in accordance with one or more embodiments. For example, the method may comprise functions or operations that are described above, for instance with reference to FIGS. 1-4.

For example, in one or more embodiments, the method may comprise indicating an identification of the power line where the apparatus is installed, in the signal that the apparatus transmits to the transceiver. An example of this step was described above with reference to FIG. 1.

In one or more embodiments, the measurement of the height of the apparatus from the ground level may comprise measuring the height for a predetermined time interval to determine whether the measured height is affected by false positives. Examples of this step was described above with reference to FIG. 1.

Although only a few example embodiments have been described in detail above, those skilled in the art will readily appreciate that many modifications are possible in the example embodiments without materially departing from this invention. Accordingly, all such modifications are intended to be included within the scope of this disclosure as defined in the following claims.

What is claimed is:

1. An apparatus for detecting a fallen power line or for detecting a sag in the power line, comprising:
a housing that is configured to be disposed on the power line;
one or more proximity sensors that are disposed on or inside the housing, wherein the one or more proximity sensors measure a height from the apparatus to a ground level below the power line;
a transmitter, wherein in response to the one or more proximity sensors measuring the height as being lower than a predetermined height threshold, the transmitter is configured to transmit a signal to a transceiver that is disposed separately from the apparatus; and
a battery that powers the transmitter and the one or more proximity sensors.

2. The apparatus according to claim 1, wherein the one or more proximity sensors measure the height using infrared radiation.

3. The apparatus according to claim 1, wherein only in response to the one or more proximity sensors measuring, continuously or discretely, the height as being lower than the predetermined height threshold for more than a predetermined time interval, the transmitter transmits the signal to the transceiver.

4. The apparatus according to claim 3, wherein the predetermined time interval is determined based on an average crossing time of inhabitants or objects that cross a space below the power line.

5. The apparatus according to claim 1, wherein the apparatus is sleeved into the power line.

6. The apparatus according to claim 1, wherein the apparatus is self-powered by the battery.

7. The apparatus according to claim 1, wherein the transmitter is a radio frequency transmitter and the signal is in radio frequency bandwidth.

8. The apparatus according to claim 1, wherein the transceiver communicates with a plurality of apparatuses, which include the apparatus, each measuring a height from a respective apparatus among the plurality of apparatuses to a respective ground level.

9. The apparatus according to claim 1, wherein the apparatus comprises a pulse generator, and the housing magnetically shields the pulse generator.

10. The apparatus according to claim 9, wherein the housing comprises an epoxy, a porcelain material, or a rubbery material to shield the pulse generator.

11. The apparatus according to claim 1, wherein the apparatus is mounted at a central location of the power line.

12. The apparatus according to claim 1, wherein the apparatus comprises one or more bracket stoppers that stop the apparatus from slipping off the power line when the power line falls.

13. The apparatus according to claim 1, wherein the transceiver boosts the signal that the transceiver receives from the transmitter of the apparatus and transmits the boosted signal to a receiver of an electric substation.

14. The apparatus according to claim 1, wherein the transmitter is configured to transmit the signal that includes an identification of the power line where the apparatus is installed, to the transceiver.

15. The apparatus according to claim 1,
wherein the transmitter comprises a pulse generator and a transmitting antenna, and
the pulse generator receives a digital input from the one or more proximity sensors and converts the digital input into radio frequency pulses that are transmitted by transmitting antenna to the transceiver as the signal.

16. A method for detecting a fallen power line or for detecting a sag in the power line by an apparatus that is disposed on the power line, the method comprising:
measuring, by one or more proximity sensors disposed on or inside a housing of the apparatus, a height of the apparatus from a ground level below the power line;
in response to the one or more proximity sensors measuring the height as being lower than a predetermined height threshold, transmitting, by a transmitter of the apparatus, a signal to a transceiver that is disposed separately from the apparatus,
wherein the transmitter and the one or more proximity sensors are powered by a battery of the apparatus;
receiving the signal, by the transceiver, from the transmitter of the apparatus;
transmitting the signal, by the transceiver, to a receiver of an electric substation;
analyzing the received signal, by the electric substation, to determine whether the power line has fallen or to determine whether the sag in the power line is more than a sag threshold; and
in response to determining that the power line has fallen or determining that the sag in the power line is more than the sag threshold, configuring a circuit breaker to shut down the power line or configuring the electric substation to raise an alarm.

17. The method according to claim 16, further comprising indicating an identification of the power line where the apparatus is installed, in the signal that the transmitter transmits to the transceiver.

18. The method according to claim 16, wherein the measuring of the height of the apparatus from the ground level comprises measuring the height for a predetermined time interval to determine whether the measured height is affected by false positives.

19. A system for detecting a fallen power line or for detecting a sag in the power line, comprising:
an apparatus that detects a height of the apparatus from a ground level below the power line, the apparatus comprising:
a housing that is configured to be disposed on the power line;
one or more proximity sensors that are disposed on or inside the housing, wherein the one or more proximity sensors measure the height of the apparatus from the ground level below the power line;
a transmitter, wherein in response to the one or more proximity sensors measuring the height as being lower than a predetermined height threshold, the transmitter is configured to transmit a signal to a transceiver that is disposed separately from the apparatus; and
a battery that powers the transmitter and the one or more proximity sensors;
the transceiver that transmits the signal to a receiver of an electric substation;
the substation that is configured to analyze the received signal to determine whether the power line has fallen or to determine whether the sag in the power line is more than a sag threshold; and
wherein the electric substation comprises a circuit breaker or an alarm system, and
wherein in response to the electric substation determining that the power line has fallen or in response to the electric substation determining that the sag in the power line is more than the sag threshold, the electric substation configures the circuit breaker to shut down the power line or configures the alarm system to raise an alarm.

20. The system according to claim 19,
wherein the electric substation converts the signal that is received by the receiver to a dry type contact (NO) tripping command, and sends the tripping command to the circuit breaker that is associated to the power line, and
wherein the electric substation configures the circuit breaker to shut down the power line based on an identification of the power line, the identification being indicated by the signal the receiver receives from the transceiver.
